(19) United States
(12) Patent Application Publication
(10) Pub. No.: US 2019/0221494 A1
(43) Pub. Date: Jul. 18, 2019

(54) SEMICONDUCTOR DEVICE

(71) Applicant: TOYOTA JIDOSHA KABUSHIKI KAISHA, Toyota-shi (JP)

(72) Inventor: Takahito MURATA, Toyota-shi (JP)

(73) Assignee: TOYOTA JIDOSHA KABUSHIKI KAISHA, Toyota-shi (JP)

(21) Appl. No.: 16/243,204

(22) Filed: Jan. 9, 2019

(30) Foreign Application Priority Data
Jan. 17, 2018 (JP) 2018-005892

(51) Int. Cl. H01L 23/367; H01L 25/07; H01L 23/00; H01L 23/047; H01L 23/08

(52) U.S. Cl. CPC H01L 23/3675; H01L 25/071; H01L 24/32; H01L 2924/14252; H01L 23/08; H01L 2224/32245; H01L 2924/13055; H01L 23/047

(57) ABSTRACT

A semiconductor device includes first and second metal plates which are disposed to face each other, a semiconductor chip, a first insulator block, and a package. The first semiconductor chip has first and second electrodes exposed on first and second surface respectively. The first and second electrodes are connected to the first and second metal plates, respectively. The first insulator block is adjacent to the first semiconductor chip, and has a first surface in contact with the first metal plate, and a second surface. The second surface is on the opposite side of the first insulator block from the first surface and is in contact with the second metal plate. The package is in contact with a surface to which the first semiconductor chip of the first metal plate is connected and a surface to which the first semiconductor chip of the second metal plate is connected.

### INCORPORATION BY REFERENCE

The disclosure of Japanese Patent Application No. 2018-005892 filed on Jan. 17, 2018 including the specification, drawings and abstract is incorporated herein by reference in its entirety.

### BACKGROUND

### 1. Technical Field

The disclosure relates to a semiconductor device in which a semiconductor chip having electrodes exposed on both surfaces is sandwiched between a pair of metal plates and is sealed between the metal plates.

### 2. Description of Related Art

Japanese Unexamined Patent Application Publication No. 2006-278591 (JP2006-278591A) and Japanese Unexamined Patent Application Publication No. 2006-049542 (JP2006-049542A) disclose semiconductor devices in which a semiconductor chip is sandwiched between a pair of metal plates and the semiconductor chip is sealed with a package. The semiconductor chip has a flat plate shape, and an electrode is exposed on each wide surface. Each of the metal plates is connected to the electrode on each surface of the semiconductor chip by solder (or solder and metal block). That is, the metal plate serves as a conductive path connecting the electrode of the semiconductor chip to other devices. In the semiconductor devices disclosed in JP2006-278591A and JP2006-049542A, one surface of each metal plate is exposed from the package and also serves as a heat sink.

JP2006-278591A discloses a jig for boding a semiconductor chip by soldering while holding a pair of metal plates in parallel. JP2006-049542A discloses a semiconductor device of a two-layer structure in which two semiconductor chips with another metal plate sandwiched therebetween are disposed between a pair of metal plates.

### SUMMARY

In the related art disclosed in JP2006-278591A, the jig for keeping a pair of metal plates parallel is used. The semiconductor device disclosed in JP2006-049542A has a two-layer structure, and it is difficult to hold a central metal plate parallel. The present disclosure relates to a semiconductor device in which a semiconductor chip is sandwiched between a pair of metal plates, is connected to each of the metal plates, and is accommodated in a package, and provides a structure capable of easily holding the metal plates parallel.

An aspect of the present disclosure relates to a semiconductor device. The semiconductor device includes a first metal plate, a second metal plate, a first semiconductor chip, a first insulator block, and a package. The first metal plate and the second metal plate are disposed to face each other. The first semiconductor chip has a first electrode exposed on a first surface, and a second electrode exposed on a second surface. The first electrode faces the first metal plate and is connected to the first metal plate by a solder, and the second electrode faces the second metal plate and is connected to the second metal plate by the solder. The first insulator block is adjacent to the first semiconductor chip, and has a first surface in contact with the first metal plate, and a second surface which is on an opposite side of the first insulator block from the first surface and is in contact with the second metal plate. The package is configured to accommodate the first semiconductor chip and be in contact with a surface of the first metal plate to which the first semiconductor chip is connected and a surface of the second metal plate to which the first semiconductor chip is connected.

In the semiconductor device, the electrode is electrically connected to the metal plate by the solder. The first metal plate and the second metal plate sandwich the first insulator block. The first insulator block holds the first metal plate and second metal plate in parallel. According to the semiconductor device according to the aspect of the present disclosure, it is possible to keep the first metal plate and the second metal plate parallel when the solder is melted, even without using a jig or the like. In the semiconductor device, the first metal plate and the second metal plate are held parallel by the insulator block, so the thickness of the solder can be made constant. A conductive member may be sandwiched between the semiconductor chip and the metal plate with the solder.

In the above aspect, the first insulator block may be located at least on both sides of the first semiconductor chip when viewed from the normal direction of the first metal plate.

In the above aspect, the first insulator block may surround three sides of the first semiconductor chip when viewed from the normal direction. The first insulator block is also useful for positioning the first semiconductor chip.

In the above aspect, the first insulator block may be located on both sides of the first semiconductor chip when viewed from the normal direction.

In the above aspect, the first semiconductor chip may include a third electrode that is provided on the first surface of the first semiconductor chip. The first insulator block may include a leg portion that faces the third electrode and extends to the outside of the package. The leg portion may include a conductive layer that is provided on a surface of the leg portion facing the third electrode, and that is connected to the third electrode and extends to the outside of the package.

In the above aspect, the first electrode may be electrically connected to the first metal plate by the solder.

The semiconductor device according to the aspect of the present disclosure may further include a third metal plate, a second semiconductor chip, and a second insulator block. The third metal plate is on an opposite side of the second metal plate from the first metal plate and faces the second metal plate. The second semiconductor chip is sandwiched between the second metal plate and the third metalplate and has a third electrode exposed on a first surface and a fourth electrode exposed on a second surface. The third electrode faces the second metal plate and is connected to the second metal plate by the solder, and the fourth electrode faces the third metal plate and is connected to the third metal plate by the solder. The second insulator block is adjacent to the second semiconductor chip, and has a first surface in contact with the second metal plate, and a second surface which is on an opposite side of the second insulator block from the first surface and is in contact with the third metal plate. The package may accommodate the first semiconductor chip and the second semiconductor chip.

In the semiconductor device, a first metal plate, an insulator block, a second metal plate, another insulator block, and a third metal plate are stacked in this order. The second metal plate which is located in the middle is sandwiched and held between insulator blocks from both sides. The semiconductor device can keep the three metal plates parallel without using a jig or the like at the time of manufacturing.

In the semiconductor device, a semiconductor chip and another semiconductor chip are connected in series. A typical circuit in which two series-connected semiconductor chips are used is an inverter that outputs three-phase alternating current. The inverter has three pairs of series connection of two switching elements. The semiconductor device according to the above aspect can be applied to an inverter.

In the semiconductor device according to the aspect, three pairs of the first semiconductor chip, the second metal plate, and the second semiconductor chip may be connected in parallel between the first metal plate and the third metal plate. With the semiconductor device according to the aspect of the present disclosure, it is possible to realize the main parts of the inverter by one package.

In the semiconductor device according to the aspect, the first semiconductor chip may include a fifth electrode that is provided on the first surface of the first semiconductor chip. The second semiconductor chip may include a sixth electrode that is provided on the first surface of the second semiconductor chip. The first insulator block may include a first leg portion that faces the fifth electrode and extends to the outside of the package. The second insulator block may include a second leg portion that faces the sixth electrode and extends to the outside of the package. The first leg portion may include a conductive layer that is provided on a surface of the first leg portion facing the fifth electrode, and that is connected to the fifth electrode and extends to the outside of the package; and the second leg portion may include a conductive layer that is provided on a surface of the second leg portion facing the sixth electrode, and that is connected to the sixth electrode and extends to the outside of the package. A transistor or the like includes a control electrode such as a gate electrode in addition to a pair of main electrodes (a collector electrode and an emitter electrode, or a source electrode and a drain electrode). The leg portion provided with the conductive layer serves as the terminal connecting the control electrode (another electrode) such as the gate electrode of the semiconductor chip to other devices. The insulator block that holds the first metal plate and the second metal plate in parallel can also serve as a terminal connecting the control electrode of the semiconductor chip to other devices.

In the above aspect, the third electrode may be electrically connected to the second metal plate by the solder.

In the semiconductor device according to the aspect, the first and second insulator blocks may be made of ceramic. The details and further improvements of the present disclosure will be described in the “DETAILED DESCRIPTION OF EMBODIMENTS” below.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a perspective view of a semiconductor device of a first embodiment;

FIG. 2 is an exploded perspective view of the semiconductor device excluding a package;

FIG. 3 is a cross-sectional view of the semiconductor device taken along line III-III of FIG. 1;

FIG. 4 is a sectional view of the semiconductor device taken along line IV-IV of FIG. 1;

FIG. 5 is a cross-sectional view of a semiconductor device of a first modification example;

FIG. 6 is an exploded perspective view showing another modification example of a ceramic block;

FIG. 7 is a perspective view of a semiconductor device of a second embodiment;

FIG. 8 is an equivalent circuit diagram of the semiconductor device of the second embodiment;

FIG. 9 is a cross-sectional view of the semiconductor device of the second embodiment taken along line IX-IX of FIG. 7;

FIG. 10 is a sectional view taken along line X-X of FIG. 7; and

FIG. 11 is a partially enlarged perspective view of an insulator block.

### DETAILED DESCRIPTION OF EMBODIMENTS

### First Embodiment

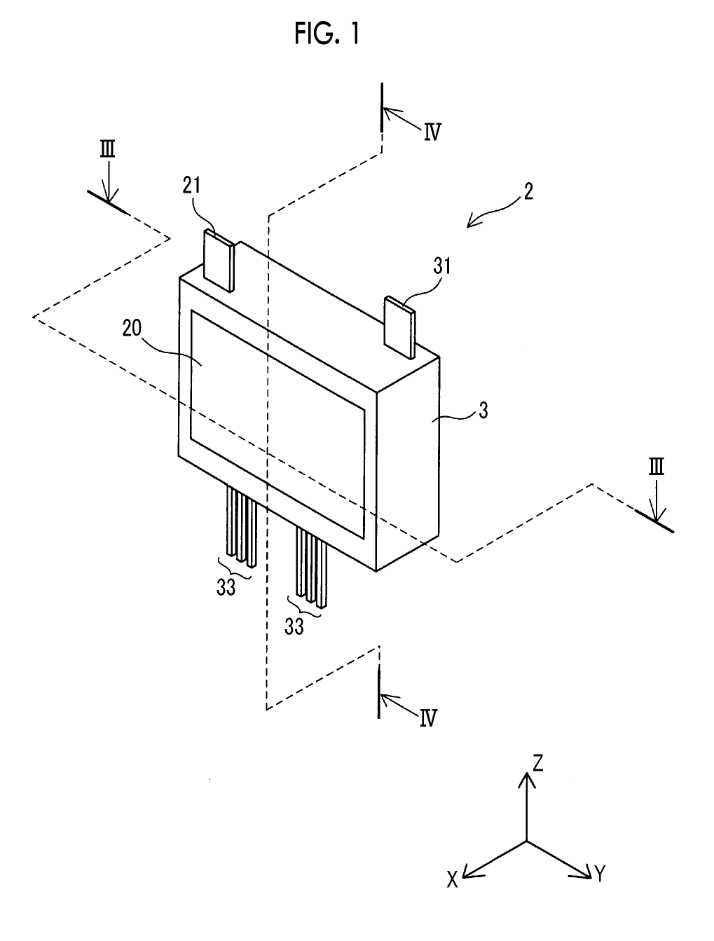

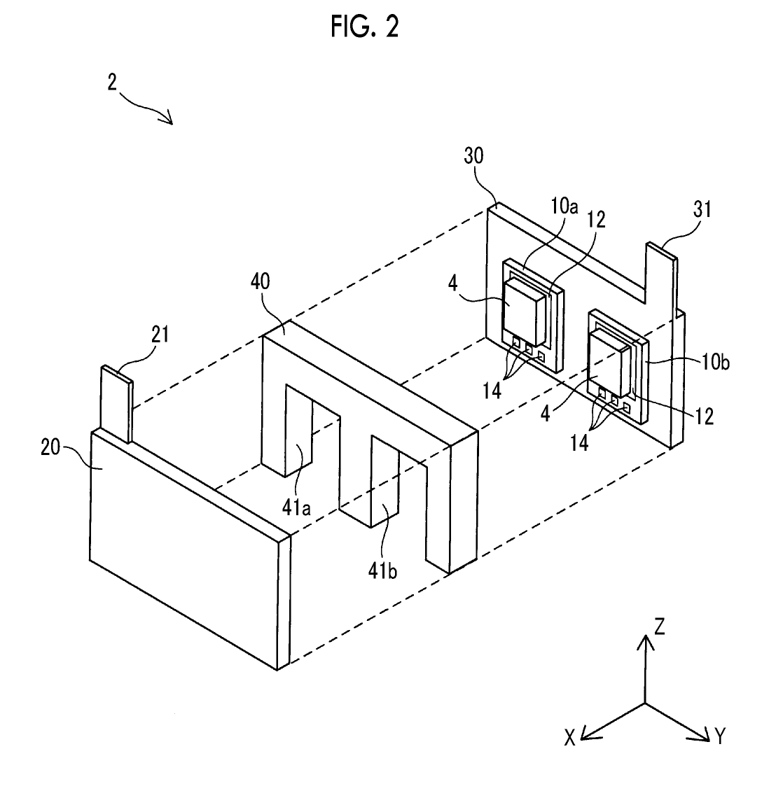

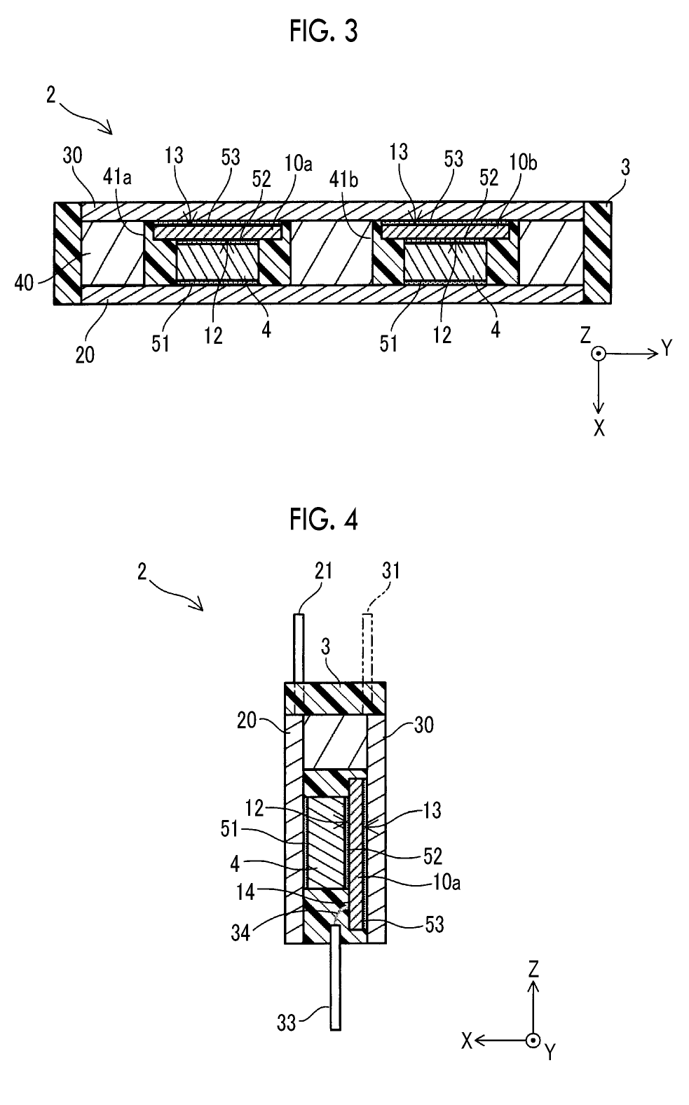

A semiconductor device 2 of a first embodiment will be described with reference to FIGS. 1 to 4. FIG. 1 is a perspective view of a semiconductor device 2. The semiconductor device 2 is a power module in which two semiconductor chips are sealed in a resin package 3. FIG. 2 is an exploded perspective view of the semiconductor device 2 excluding the package 3. FIG. 3 is a cross-sectional view taken along line III-III of FIG. 1, and FIG. 4 is a sectional view taken along line IV-IV of FIG. 1. FIG. 3 illustrates a cross section across a semiconductor chip 10a, 10b. FIG. 4 illustrates a section across the semiconductor chips 10a. For convenience of description, the +Z direction of the coordinate system in the drawings is defined as “upper”, and the −Z direction is defined as “lower”.

In addition to the package 3, the semiconductor device 2 includes a positive electrode metal plate 20, a negative electrode metal plate 30, two semiconductor chips 10a, 10b, a ceramic block 40, and a copper block 4. Hereinafter, the positive electrode metal plate 20 and the negative electrode metal plate 30 may be collectively referred to as a pair of metal plates 20, 30.

The package 3 is flat, the positive electrode metal plate 20 is exposed on one of two wide surfaces, and the negative electrode metal plate 30 is exposed on the other wide surface. A positive electrode terminal 21 and a negative electrode terminal 31 extend from one narrow surface (upper surface) sandwiched between the wide surfaces, and a plurality of control terminals 33 extends from the lower surface. The control terminal 33 is made of a conductive metal. The positive electrode metal plate 20 and the negative electrode metal plate 30 exposed on the wide surfaces are thermally connected to the semiconductor chips 10a, 10b inside the package 3 and serve as heat sinks for dissipating the heat of the semiconductor chips 10a, 10b as well.

The semiconductor chips 10a, 10b are Reverse-Conducting Insulated Gate Bipolar Transistors (RC-IGBTs) in which transistors and diodes are connected in anti-parallel. The RC-IGBT is often used in voltage converters and inverters. The semiconductor chips 10a, 10b are of a flat plate type, a collector electrode 12 is exposed on the first surface, and an emitter electrode 13 is exposed on the second surface. On the first surface, in addition to the collector electrode 12, a plurality of control electrodes 14 such as a gate electrode and a sense emitter electrode is provided.

The ceramic block 40 has an E shape as viewed from the normal direction of the positive electrode metal plate 20 (the X direction in the drawings), and has two slits 41a, 41b surrounding the three sides. The positive electrode metal plate 20 is in contact with the first surface of the ceramic block 40 and the negative electrode metal plate 30 is in contact with the second surface which is a surface on the opposite side of the ceramic block 40. In other words, the ceramic block 40 is sandwiched between the positive electrode metal plate 20 and the negative electrode metal plate 30. The semiconductor chip 10a and the copper block 4 are disposed in one slit 41a of the ceramic block 40, and the semiconductor chip 10b and another copper block 4 are disposed in the other slit 41b. The semiconductor chip 10a and the copper block 4 are sandwiched between the positive electrode metal plate 20 and the negative electrode metal plate 30. The semiconductor chip 10b and another copper block 4 are sandwiched between the positive electrode metal plate 20 and the negative electrode metal plate 30.

The copper block 4 is bonded to the collector electrode 12 of the semiconductor chip 10a by a solder 52 and the negative electrode metal plate 30 is bonded to the emitter electrode 13 which is on the opposite side from the collector electrode 12 by a solder 53. The opposite side of the copper block 4 from the semiconductor chip 10a is bonded to the positive electrode metal plate 20 by a solder 51.

The copper block 4 is bonded to the collector electrode 12 of the semiconductor chip 10b by a solder 52 and the negative electrode metal plate 30 is bonded to the emitter electrode 13 which is on the opposite side from the collector electrode 12 by a solder 53. The opposite side of the copper block 4 from the semiconductor chip 10b is bonded to the positive electrode metal plate 20 by a solder 51.

The semiconductor chips 10a, 10b are connected in parallel by the metal plates 20, 30. The positive electrode terminal 21 extends from the edge of the positive electrode metal plate 20, and the positive electrode terminal 21 extends out of the package 3. The negative electrode terminal 31 extends from the edge of the negative electrode metal plate 30, and the negative electrode terminal 31 extends out of the package 3. The semiconductor device 2 incorporates two semiconductor chips 10a, 10b, but the two semiconductor chips 10a, 10b are connected in parallel, and the semiconductor device 2 operates like a single semiconductor chip. Since the semiconductor device 2 can distribute the load to the two semiconductor chips 10a, 10b, the allowable power is large. The semiconductor device 2 is suitable for a power converter handling high power.

As illustrated in FIG. 4, the control electrode 14 is connected to the control terminal 33 through a bonding wire 34.

The ceramic block 40 holds a state in which the metal plates 20, 30 face each other in parallel. In the semiconductor device 2, before the package 3 is formed by injection molding, the semiconductor chips 10a, 10b and the copper blocks 4 are bonded to the metal plates 20, 30 by solder 51 to 53. By the ceramic block 40, the metal plates 20, 30 are kept parallel to each other before bonding. The solder material is melted between the metal plates 20, 30 which are kept parallel, and the semiconductor chips 10a, 10b and the copper block 4 are bonded. Bonding with a solder material is performed in a reflow process. Even if the solder melts, the metal plates 20, 30 are held parallel. Since the solder material melts and solidifies between the metal plates 20, 30 kept parallel, a solder layer having a uniform thickness can be obtained. One advantage of the ceramic block 40 is that it is possible to keep the metal plates 20, 30 parallel when the solders 51 to 53 are melted even without using a jig and to make the thickness of the solders 51 to 53 uniform.

The ceramic block 40 also serves to determine the position of the semiconductor chip 10a (10b) by causing the semiconductor chip 10a (10b) to be disposed in the slit 41a (41b) surrounding the three sides. This point is another advantage of the ceramic block 40.

It is possible to reduce the amount of resin which is the material of the package, by embedding the ceramic block 40 in the resin package 3.

The semiconductor device 2 with metal plates exposed on both surfaces may be used by placing a cooler on both surfaces. In the semiconductor device 2 which is pressed against the cooler from both surfaces, the ceramic block 40 also contributes to the strength of the package 3.

Since the metal plates 20, 30 exposed from the package 3 also serve as the terminals of the semiconductor chips 10a, 10b, an insulating thin plate may be pasted to the exposed surface by an anodic bonding method or the like. The insulating thin plates may be pasted prior to the formation of the package 3 by injection molding. The insulating thin plate may be a plate made of, for example, Si₂Al, AlN, or the like.

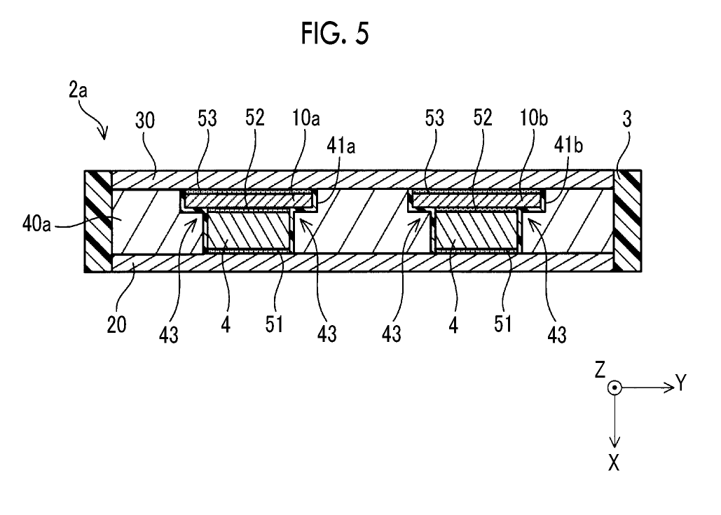

In FIG. 5, a cross-sectional view of a semiconductor device 2a of a modification example is illustrated. In the semiconductor device 2a, the shape of the ceramic block 40a is different from the shape of the ceramic block 40 described above. The ceramic block 40a is provided with steps 43 on the inner surfaces of the slits 41a, 41b. The step 43 is useful for positioning the copper block 4 which is smaller than the semiconductor chips 10a, 10b when viewed from the X direction. The ceramic block 40a surrounds the copper block 4 with a small clearance by the step 43 to reduce the margin for movement of the copper block 4 before boding. The ceramic block 40a can determine not only the positions of the semiconductor chips 10a, 10b but also the position of the copper block 4 in the planar direction.

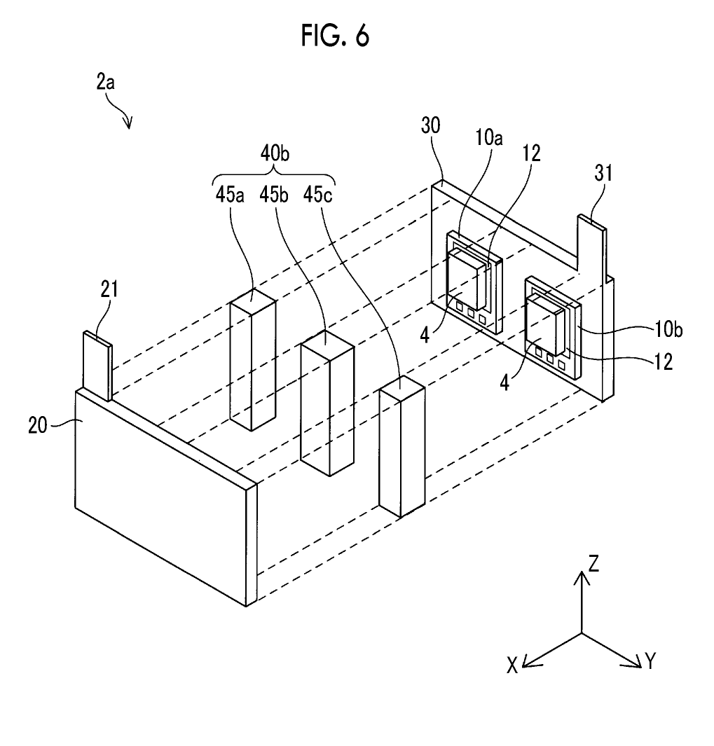

In FIG. 6, an exploded perspective view of a semiconductor device 2b including a ceramic block 40b of another modification example is illustrated. In FIG. 6, the package 3 is excluded as in FIG. 2. The ceramic block 40b is divided into three ceramic pillars 45a, 45b, 45c. The ceramic pillars 45a, 45b are located on both sides of the semiconductor chip 10a. The ceramic pillars 45b and 45c are located on both sides of the semiconductor chip 10b. The ceramic block 40b can determine the positions of the semiconductor chips 10a, 10b in the Y direction in the coordinate system in the drawings. Although it is desirable that the ceramic block surrounds three sides of the semiconductor chip when viewed from the normal direction (X direction) of the metal plates 20, 30, the ceramic block being located in both directions when viewed from the normal direction contributes to positioning.

### Second Embodiment

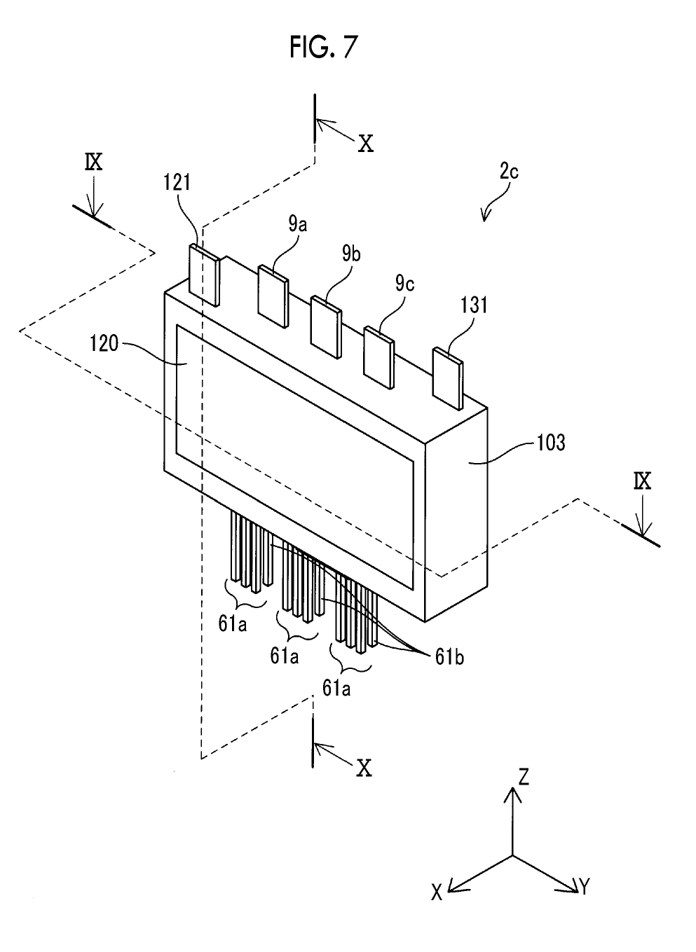

A semiconductor device 2c of a second embodiment will be described with reference to FIGS. 7 to 11. The semiconductor device 2 of the first embodiment accommodates two semiconductor chips 10a, 10b connected in parallel, in the package 3 of the semiconductor device 2. The semiconductor device 2c of the second embodiment accommodates six semiconductor chips 10a to 10f, in the package 103. The six semiconductor chips 10a to 10f are connected in series two by two. Three pairs of series connections are connected in parallel. One semiconductor device 2c can realize the main parts of the three-phase AC inverter.

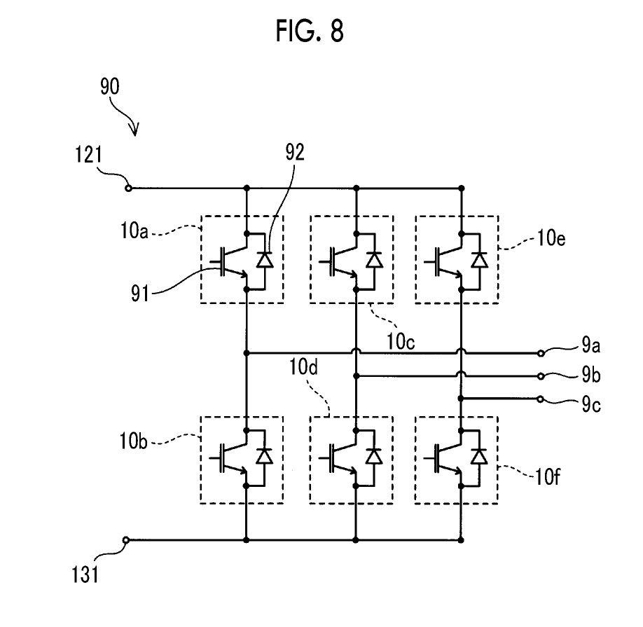

FIG. 7 illustrates a perspective view of a semiconductor device 2c, and FIG. 8 illustrates an equivalent circuit diagram of the semiconductor device 2c. In FIG. 8, the circuit in the broken-line rectangle indicated by each of the reference numerals 10a to 10f is an equivalent circuit of one semiconductor chip. Each semiconductor chip has a circuit structure in which a transistor 91 (IGBT) and a diode 92 are connected in anti-parallel. The circuit structure is the RC-IGBT described above. The semiconductor chips 10a, 10b are connected in series, the semiconductor chips 10c and 10d are connected in series, and the semiconductor chips 10e and 10f are connected in series. Three pairs of series connections are connected in parallel between the positive electrode terminal 121 and the negative electrode terminal 131. The midpoint of each of the three pairs of series connection is connected to the output terminals 9a to 9c.

As illustrated in FIG. 7, like the semiconductor device 2 of the first embodiment, the semiconductor device 2c has a flat package 103, and a positive electrode metal plate 120 and a negative electrode metal plate 130 are exposed on the wide surface of the package 103. In FIG. 7, the negative electrode metal plate 130 is located on the rear surface of the package 103 and cannot be seen. A positive electrode terminal 121, a negative electrode terminal 131, and output terminals 9a to 9c extend from the upper surface which is one of the narrow surfaces, and control terminals (leg portions 61a and 61b of the ceramic block) extend from the lower surface. There are a total of six control terminals, and each is connected to one semiconductor chip.

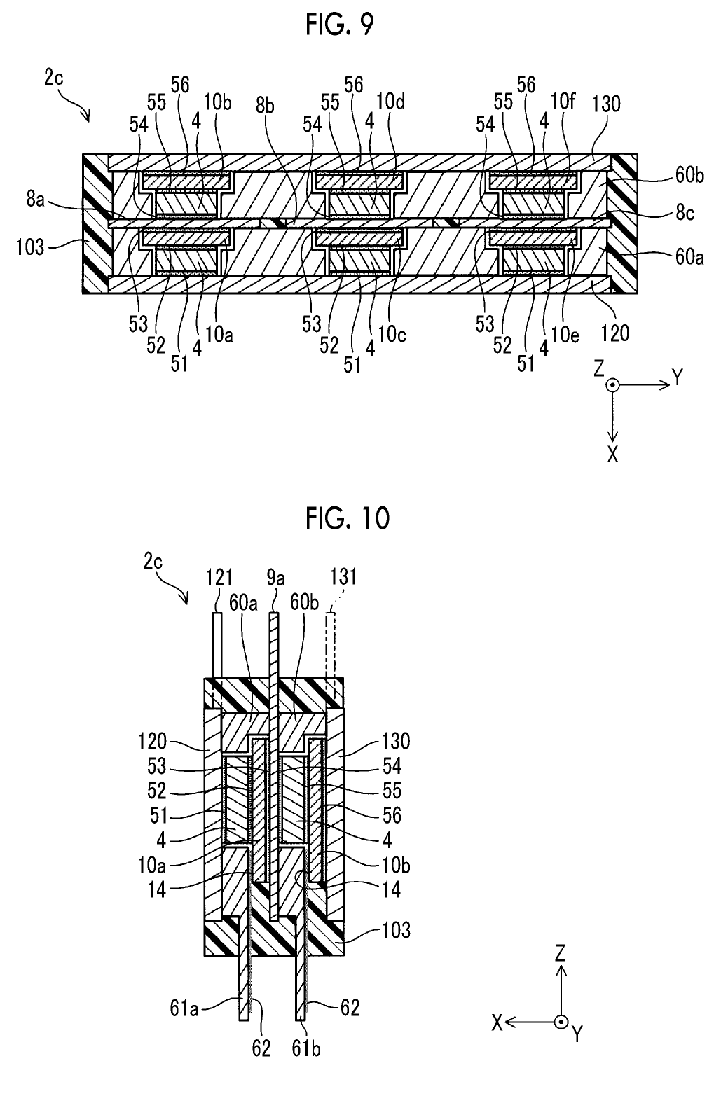

FIG. 9 illustrates a sectional view taken along line IX-IX of FIG. 7, and FIG. 10 illustrates a cross sectional view taken along line X-X of FIG. 7. Inside the semiconductor device 2c, a two-layer structure is formed in the normal direction (the X direction in the drawing) of a pair of metal plates 120, 130 provided such that the metal plates 120, 130 face each other. Six semiconductor chips 10a to 10f, three intermediate metal plates 8a to 8c, two ceramic blocks 60a, 60b, and a plurality of copper blocks 4 are sandwiched between the metal plates 120, 130. FIG. 10 illustrates a section across the semiconductor chips 10a, 10b.

The copper block 4 and the semiconductor chip 10a are sandwiched between the positive electrode metal plate 120 and the first intermediate metal plate 8a. The semiconductor chip 10a is of the same flat plate type as the chip of the first embodiment, the collector electrode is exposed on one wide surface, and the emitter electrode is exposed on the other wide surface. The control electrode 14 is also provided in on one wide surface. In FIG. 9, symbols for the collector electrodes and the emitter electrodes are omitted, but collector electrodes and control electrodes are provided on the lower surface of the semiconductor chip 10a, and emitter electrodes are provided on the upper surface. The same applies to other semiconductor chips.

The copper block 4 is bonded to the collector electrode of the semiconductor chip 10a by solder 52 and the first intermediate metal plate 8a is bonded to the emitter electrode which is on the opposite side from the collector electrode by solder 53. The opposite side of the copper block 4 from the semiconductor chip 10a is bonded to the positive electrode metal plate 120 by solder 51.

The copper block 4 and the semiconductor chip 10b are sandwiched between the first intermediate metalplate 8a and the negative electrode metalplate 130, on the opposite side from the positive electrode metal plate 120. The semiconductor chip 10b is of the same flat plate type as the chip of the first embodiment, the collector electrode is exposed on one wide surface, and the emitter electrode is exposed on the other wide surface. The control electrode is also provided in on one wide surface.

The copper block 4 is bonded to the collector electrode of the semiconductor chip 10b by solder 55 and the negative electrode metal plate 130 is bonded to the emitter electrode which is on the opposite side from the collector electrode by solder 56. The opposite side of the copper block 4 from the semiconductor chip 10b is bonded to the first intermediate metal plate 8a by solder 54.

The semiconductor chips 10a, 10b are connected in series with the first intermediate metal plate 8a sandwiched therebetween. The semiconductor chip 10a is positioned on the high potential side and the semiconductor chip 10b is positioned on the low potential side. The series connection of the semiconductor chips 10a, 10b is sandwiched between the positive electrode metal plate 120 and the negative electrode metal plate 130. The collector electrode and the emitter electrode of the semiconductor chips 10a, 10b are connected to the positive electrode metal plate 120 and the negative electrode metal plate 130 by the solders 51 to 56 and the copper block 4.

The semiconductor chips 10c and 10d and the second intermediate metal plate 8b also have the same structure as the semiconductor chips 10a, 10b and the first intermediate metal plate 8a. The semiconductor chips 10c and 10d are connected in series with the second intermediate metal plate 8b sandwiched therebetween. The semiconductor chip 10c is positioned on the high potential side and the semiconductor chip 10d is positioned on the low potential side. The series connection of the semiconductor chips 10c and 10d is sandwiched between the positive electrode metal plate 120 and the negative electrode metal plate 130. The collector electrode and the emitter electrode of the semiconductor chips 10c and 10d are connected to the positive electrode metal plate 120 and the negative electrode metalplate 130 by the solders 51 to 56 and the copper block 4.

The semiconductor chips 10e and 10f and the third intermediate metal plate 8c also have the same structure as the semiconductor chips 10a, 10b and the first intermediate metal plate 8a. The semiconductor chips 10e and 10f are connected in series with the third intermediate metal plate 8c sandwiched therebetween. The semiconductor chip 10e is positioned on the high potential side and the semiconductor chip 10f is positioned on the low potential side. The series connection of the semiconductor chips 10e and 10f is sandwiched between the positive electrode metal plate 120 and the negative electrode metal plate 130. The collector electrode and the emitter electrode of the semiconductor chips 10e and 10f are connected to the positive electrode metal plate 120 and the negative electrode metal plate 130 by the solders 51 to 56 and the copper block 4.

As described above, three pairs of series connection of two semiconductor chips are connected in parallel between the positive electrode metal plate 120 and the negative electrode metal plate 130.

The six semiconductor chips 10a to 10f and the three intermediate metal plates 8a to 8c are sealed in a resin package 103.

The positive electrode terminal 121 is connected to the edge of the positive electrode metal plate 120, and the negative electrode terminal 131 is connected to the edge of the negative electrode metal plate 130. As illustrated in FIG. 7, the positive electrode terminal 121 and the negative electrode terminal 131 extend outward from the upper surface of the package 103.

The first output terminal 9a is connected to the first intermediate metal plate 8a. Similarly, the second output terminal 9b is connected to the second intermediate metal plate 8b, and the third output terminal 9c is connected to the third intermediate metal plate 8c. As illustrated in FIG. 7, three output terminals 9a to 9c extend outward from the upper surface of the package 103.

As described above, the semiconductor device 2c realizes the circuit represented by the equivalent circuit of FIG. 8, and one semiconductor device can constitute an inverter.

The ceramic block 60a is sandwiched between the positive electrode metal plate 120 and the three intermediate metal plates 8a to 8c. In the ceramic block 60a, the first surface is in contact with the positive electrode metal plate 120, and the second surface, which a surface on the opposite side, is in contact with the intermediate metal plates 8a to 8c. In the ceramic block 60a, slits surrounding three sides are provided, and semiconductor chips are disposed in the slits. The ceramic block 60a has three slits, and each of the three semiconductor chips 10a, 10c, 10e is positioned in a corresponding one of the slits.

The ceramic block 60a holds the positive electrode metalplate 120 and the intermediate metal plates 8a to 8c parallel. Therefore, similar to the semiconductor device 2 of the first embodiment, even if the solders 51 to 53 melt, the positive electrode metal plate 120 and the intermediate metal plates 8a to 8c are kept parallel. The thickness of each layer of the solders 51 to 53 is kept constant.

The ceramic block 60b is sandwiched between the negative electrode metal plate 130 and the three intermediate metal plates 8a to 8c. In the ceramic block 60b, the first surface is in contact with the negative electrode metal plate 130, and the second surface, which a surface on the opposite side, is in contact with the intermediate metal plates 8a to 8c. In the ceramic block 60b, slits surrounding three sides are provided, and semiconductor chips are disposed in the slits. The ceramic block 60b has three slits, and each of the three semiconductor chips 10b, 10d, 10f is positioned in each of the slits.

The ceramic block 60b holds the negative electrode metal plate 130 and the intermediate metal plates 8a to 8c parallel. Therefore, similar to the semiconductor device 2 of the first embodiment, even if the solders 54 to 56 melt, the negative electrode metal plate 130 and the intermediate metal plates 8a to 8c are kept parallel. The thickness of each layer of the solders 54 to 56 is kept constant.

The semiconductor device 2c has a two-layer structure in which the intermediate metal plate 8a (8b, 8c) is sandwiched between the positive electrode metal plate 120 and the negative electrode metal plate 130, and the positive electrode metal plate 120, the negative electrode metalplate 130, and the intermediate metalplate 8a (8b, 8c) are parallel to each other. The ceramic blocks 60a, 60b hold the positive electrode metal plate 120, the negative electrode metal plate 130, and the intermediate metal plate 8a (8b, 8c) parallel even when the solder melts.

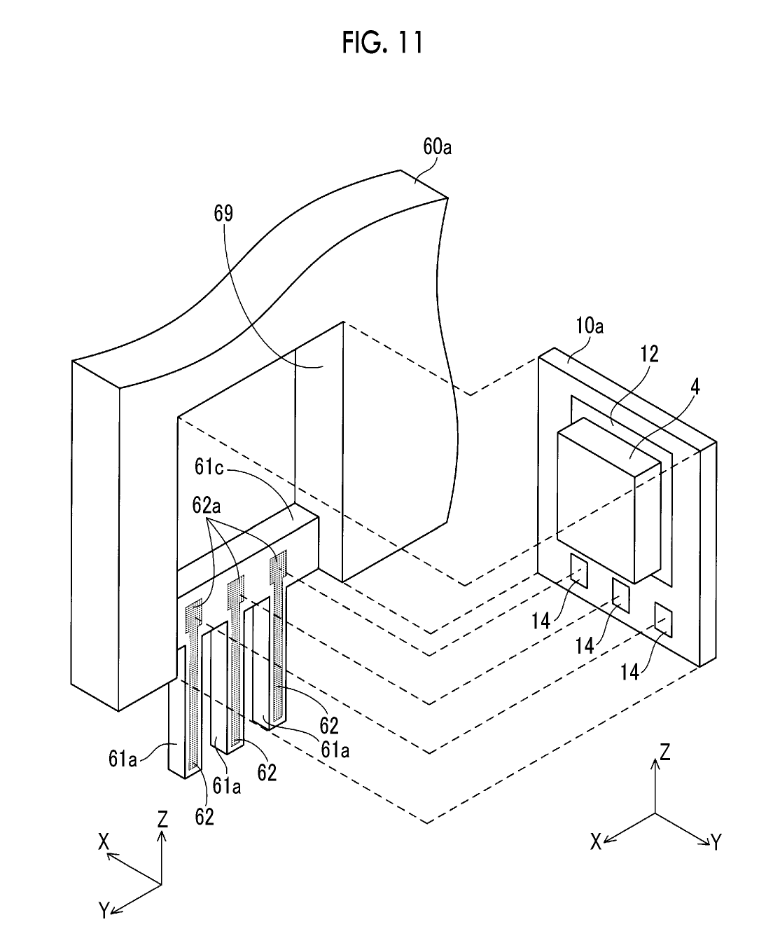

In the ceramic block 60a, a plurality of leg portions 61a extending from the inside of the package 103 to the outside is provided. FIG. 11 illustrates a partially enlarged perspective view of the ceramic block 60a. FIG. 11 is an enlarged view of the periphery of the slit 69. The semiconductor chip 10a is disposed in the slit 69. In FIG. 11, the semiconductor chip 10a is also drawn. Note that in FIG. 11, the orientations of the coordinate axes are different on the right side and the left side. Similar to the first embodiment, the position of the semiconductor chip 10a in the YZ plane is determined by disposing the semiconductor chip 10a in the slit 69 surrounding the three sides.

The leg portions 61a extend from a leg base 61c which is stretched over the edge of the slit 69 of the ceramic block 60a. The leg base 61c faces the control electrode 14 of the semiconductor chip 10a when the semiconductor chip 10a is disposed in the slit 69. The conductive layer 62 is provided from the position of the leg base 61c facing the control electrode 14 to the tip of the leg portion 61a. In FIG. 11, the conductive layer 62 is shown in gray to ease understanding. The conductive layer 62 is formed on the surface of the leg portion 61a using a printing technique.

The leg portion 61a extends together with the conductive layer 62 to the outside of the package 103 (see FIG. 10). When the semiconductor chip 10a is disposed in the slit 69, and the semiconductor chip 10a is bonded to other parts by solders 51 to 53, the control electrode 14 is bonded to the upper end 62a of the conductive layer 62. The control electrode 14 is bonded to the upper end 62a of the conductive layer 62 by a solder bump (not shown). The control electrode 14 and the conductive layer 62 conduct through the solder bump. The control electrode 14 of the semiconductor chip 10a is connected to an external device by the leg portion 61a extending to the outside of the package 103 and the conductive layer 62.

In the semiconductor device 2 of the first embodiment, the control electrode 14 is connected to an external device by the bonding wire 34 and the control terminal 33 (see FIG. 4). In the semiconductor device 2c of the second embodiment, leg portions 61a are provided in the ceramic block 60a which holds the metal plates parallel, and the leg portions 61a serve as control terminals. In the semiconductor device 2c, since the bonding wire 34 needs not for the conductive path connecting the control electrode 14 to the outside, manufacturing cost can be suppressed.

The ceramic block 60a has the same leg portion 61a and the same conductive layer 62 as the other semiconductor chips 10c and 10e. The ceramic block 60b also has a leg portion 61b of the same structure as the leg portion 61a of the ceramic block 60a.

A part of the slit 69 is narrowed by the leg base 61c. In the space of the slit 69, the copper block 4 bonded to the collector electrode 12 of the semiconductor chip 10a is disposed. The space of the slit 69 narrowed by the leg base 61c contributes to the positioning of the copper block 4.

In a semiconductor device having a two-layer structure in which three metal plates are disposed in parallel while facing each other, it is difficult to keep the metal plates parallel. In the semiconductor device 2c of the second embodiment, since the two ceramic blocks 60a, 60b sandwich the intermediate metal plates 8a to 8c from both sides, the intermediate metal plates 8a to 8c are kept parallel.

Notes on the technique described in the embodiment will be described. The semiconductor device of the embodiment accommodates the semiconductor chip of RC-IGBT in the package. In the present disclosure, a semiconductor chip having another function may be used. Further, in the present disclosure, the number of semiconductor chips accommodated in the package is not limited. In the present disclosure, the number of other metal plates sandwiched between the metal plates at both ends in the stacking direction is also not limited. The number of layers of the semiconductor chip formed between the metal plates at both ends in the stacking direction is also not limited.

The ceramic blocks 40, 60a, 60b are examples of the insulator block. The ceramic block has high insulation and high rigidity, so the ceramic block is suitable for the semiconductor device of the embodiment. It is desirable that the insulator block is made of ceramic, but it is not limited to ceramic. The insulator block may be a metal block covered with an insulating film. Alternatively, the insulator block may be made of resin.

The positive electrode metal plate 20 of the first embodiment is an example of the first metal plate and the negative electrode metal plate 30 is an example of the second metal plate. The positive electrode metalplate 120 of the second embodiment is an example of the first metal plate and the negative electrode metal plate 130 is an example of the third metal plate. The intermediate metal plates 8a to 8c are examples of the second metal plate.

The copper block 4 is a spacer that electrically connects the electrode of the semiconductor chip and the metal plate. Instead of the copper block 4, a spacer made of another conductive material may be used. When the thickness of the semiconductor chip is large, a spacer may not be used.

Although specific examples of the present disclosure have been described in detail above, the examples are merely illustrative and do not limit the scope of the claims. The techniques described in the claims include various modifications and changes of the specific examples illustrated above. The technical elements described in this specification or the drawings exhibit technical usefulness singly or in various combinations, and are not limited to the combination described in the claims at the time of filing. A plurality objects can be achieved at the same time by the technique illustrated in this description or drawings, the technique has technical usefulness by achieving one of the objects.

What is claimed is:

1. A semiconductor device comprising:
a first metal plate and a second metal plate disposed to face each other;
a first semiconductor chip having a first electrode exposed on a first surface and a second electrode exposed on a second surface, the first electrode facing the first metal plate and being connected to the first metal plate by a solder, and the second electrode facing the second metal plate and being connected to the second metal plate by the solder;
a first insulator block adjacent to the first semiconductor chip, the first insulator block having
a first surface in contact with the first metal plate, and
a second surface which is on an opposite side of the first insulator block from the first surface and is in contact with the second metal plate; and
a package configured to accommodate the first semiconductor chip and be in contact with a surface of the first metal plate to which the first semiconductor chip is connected and a surface of the second metal plate to which the first semiconductor chip is connected.

2. The semiconductor device according to claim 1, wherein the first insulator block is located at least on both sides of the first semiconductor chip when viewed from a normal direction of the first metal plate.

3. The semiconductor device according to claim 2, wherein the first insulator block surrounds three sides of the first semiconductor chip when viewed from the normal direction.

4. The semiconductor device according to claim 2, wherein the first insulator block is located on both sides of the first semiconductor chip when viewed from the normal direction.

5. The semiconductor device according to claim 1, wherein:
the first semiconductor chip includes a third electrode that is provided on the first surface of the first semiconductor chip;
the first insulator block includes a leg portion that faces the third electrode and extends to the outside of the package; and the leg portion includes a conductive layer that is provided on a surface of the leg portion facing the third electrode, and that is connected to the third electrode and extends to the outside of the package.

6. The semiconductor device according to claim 1, wherein the first electrode is electrically connected to the first metal plate by the solder.

7. The semiconductor device according to claim 1, further comprising a first conductive member being sandwiched between the first semiconductor chip and the first metal plate with the solder.

8. The semiconductor device according to claim 1, further comprising:
a third metal plate that is on an opposite side of the second metal plate from the first metal plate and faces the second metal plate;
a second semiconductor chip sandwiched between the second metal plate and the third metal plate, the second semiconductor chip having a third electrode exposed on a first surface and a fourth electrode exposed on a second surface, the third electrode facing the second metalplate and being connected to the second metal plate by the solder, and the fourth electrode facing the third metalplate and being connected to the third metal plate by the solder; and
a second insulator block adjacent to the second semiconductor chip, the second insulator block having
a first surface in contact with the second metal plate, and
a second surface which is on an opposite side of the second insulator block from the first surface and is in contact with the third metal plate,
wherein the package accommodates the first semiconductor chip and the second semiconductor chip.

9. The semiconductor device according to claim 8, wherein three pairs of the first semiconductor chip, the second metal plate, and the second semiconductor chip are connected in parallel between the first metal plate and the third metal plate.

10. The semiconductor device according to claim 8, wherein:
the first semiconductor chip includes a fifth electrode that is provided on the first surface of the first semiconductor chip;
the second semiconductor chip includes a sixth electrode that is provided on the first surface of the second semiconductor chip;
the first insulator block includes a first leg portion that faces the fifth electrode and extends to the outside of the package;
the second insulator block includes a second leg portion that faces the sixth electrode and extends to the outside of the package;
the first leg portion includes a conductive layer that is provided on a surface of the first leg portion facing the fifth electrode, and that is connected to the fifth electrode and extends to the outside of the package; and
the second leg portion includes a conductive layer that is provided on a surface of the second leg portion facing the sixth electrode, and that is connected to the sixth electrode and extends to the outside of the package.

11. The semiconductor device according to claim 8, wherein the third electrode is electrically connected to the second metal plate by the solder.

12. The semiconductor device according to claim 8, further comprising a second conductive member being sandwiched between the second semiconductor chip and the second metal plate with the solder.

13. The semiconductor device according to claim 1, wherein the first insulator block is made of ceramic.

14. The semiconductor device according to claim 8, wherein the first and second insulator blocks are made of ceramic.
